(19) United States
(12) Patent Application Publication
(10) Pub. No.: US 2023/0138616 A1
(43) Pub. Date: May 4, 2023

(54) SEMICONDUCTOR DEVICE AND SEMICONDUCTOR PACKAGE INCLUDING THE SAME

(71) Applicant: Samsung Electronics Co., Ltd., Suwon-si (KR)

(72) Inventors: Minjung Choi, Suwon-si (KR); Jongmin Lee, Hwaseong-si (KR); Yeonjin Lee, Suwon-si (KR); Jeonil Lee, Suwon-si (KR); Jimin Choi, Seoul (KR)

(73) Assignee: Samsung Electronics Co., Ltd., Suwon-si (KR)

(21) Appl. No.: 18/051,623

(22) Filed: Nov. 1, 2022

(30) Foreign Application Priority Data
Nov. 3, 2021 (KR) 10-2021-0149956

(51) Int. Cl. H01L 21/02; H01L 23/14; H01L 23/31; H01L 25/065

(52) U.S. Cl. CPC H01L 21/02021; H01L 21/02035; H01L 23/147; H01L 23/3128; H01L 25/0657

(57) ABSTRACT

A semiconductor device including a semiconductor substrate, a first interlayer insulating layer arranged on the semiconductor substrate, a low dielectric layer arranged on the first interlayer insulating layer, a second interlayer insulating layer and a third interlayer insulating layer sequentially arranged on the low dielectric layer, and a through silicon via penetrating the semiconductor substrate and the first interlayer insulating layer, wherein the semiconductor substrate, the first interlayer insulating layer, and the low dielectric layer constitute a chamfered structure including a first chamfered surface parallel to the top surface of the semiconductor substrate and a second chamfered surface inclined with respect to the top surface of the semiconductor substrate and connected to the first chamfered surface may be provided.

### CROSS-REFERENCE TO RELATED APPLICATION

This application is based on and claims priority under 35 U.S.C. §119 to Korean Patent Application No. 10-2021-0149956, filed on Nov. 3, 2021, in the Korean Intellectual Property Office, the disclosure of which is incorporated by reference herein in its entirety.

### BACKGROUND

The inventive concepts relate to a semiconductor devices. More particularly, the inventive concepts relate to semiconductor devices having a chamfered structure, and/or semiconductor packages including the semiconductor device.

In response to the rapid development of the electronics industry and the demand of users, electronic devices are becoming smaller and lighter. Accordingly, a high integration density of semiconductor chips used in an electronic device is required, and design rules for the components of the semiconductor chip have been further reduced. In addition, low dielectric layers have been introduced in the semiconductor chips to reduce parasitic capacitance between wirings and a resistive-capacitive (RC) delay. Meanwhile, there is a need for a structure capable of preventing cracking and chipping of a semiconductor chip in a semiconductor chip separation process.

### SUMMARY

The inventive concepts provide semiconductor devices capable of preventing a crack and simplifying a fabrication process thereof.

The inventive concepts also provide semiconductor packages including a semiconductor device capable of preventing or mitigating a crack and simplifying a fabrication process thereof.

According to an example embodiment, a semiconductor device includes a semiconductor substrate comprising a chip area and a scribe lane area, the chip area including a plurality of memory cells, a scribe lane area horizontally surrounding the chip area, a first interlayer insulating layer on the semiconductor substrate in the chip area and the scribe lane area, a low dielectric layer on the first interlayer insulating layer in the chip area and the scribe lane area, a second interlayer insulating layer on the low dielectric layer in the chip area and the scribe lane area, a third interlayer insulating layer on the second interlayer insulating layer in the chip area and the scribe lane area, and a through silicon via penetrating the semiconductor substrate and the first interlayer insulating layer in a direction perpendicular to a top surface of the semiconductor substrate in the chip area, wherein each of the semiconductor substrate, the first interlayer insulating layer, and the low dielectric layer comprises a chamfered structure that includes a first chamfered surface and a second chamfered surface, the first chamfered surface being parallel to the top surface of the semiconductor substrate, the second chamfered surface being inclined with respect to the top surface of the semiconductor substrate and connected to the first chamfered surface.

According to an example embodiment, a semiconductor device includes a semiconductor substrate comprising a chip area and a scribe lane area, the chip area including a plurality of memory cells, the scribe lane area horizontally surrounding the chip area, a first interlayer insulating layer on the semiconductor substrate in the chip area and the scribe lane area, a low dielectric layer on the first interlayer insulating layer in the chip area and the scribe lane area, a lower wiring layer in the low dielectric layer in the chip area, a second interlayer insulating layer on the low dielectric layer in the chip area and the scribe lane area, an upper wiring layer in the second interlayer insulating layer in the chip area, a third interlayer insulating layer on the second interlayer insulating layer in the chip area and the scribe lane area, and a through silicon via penetrating the semiconductor substrate and the first interlayer insulating layer in a direction perpendicular to a top surface of the semiconductor substrate in the chip area, wherein a first side surface of the semiconductor substrate, a second side surface of the first interlayer insulating layer, and a third side surface of the low dielectric layer are inclined with respect to the top surface of the semiconductor substrate.

According to an example embodiment, a semiconductor package includes a base chip comprising a first semiconductor substrate, the first semiconductor substrate including a first chip area and a first scribe lane area, the first chip area including a plurality of memory cells, the first scribe lane area horizontally surrounding the first chip area, the base chip including a first lower interlayer insulating layer on the first semiconductor substrate in the first chip area and the first scribe lane area, a first low dielectric layer on the first lower interlayer insulating layer in the first chip area and the first scribe lane area, a first upper interlayer insulating layer on the first low dielectric layer in the first chip area and the first scribe lane area, and a first uppermost interlayer insulating layer on the first upper interlayer insulating layer in the first chip area and the first scribe lane area, a memory chip arranged on the base chip, and micro-bumps between the base chip and the memory chip and connecting the base chip and the memory chip to each other, wherein the base chip has a chamfered structure that includes a first chamfered surface and a second chamfered surface, the first chamfered surface being parallel to a top surface of the first semiconductor substrate, the second chamfered surface being inclined with respect to the top surface of the first semiconductor substrate and connected to the first chamfered surface.

### BRIEF DESCRIPTION OF THE DRAWINGS

Some example embodiments of the inventive concepts will be more clearly understood from the following detailed description taken in conjunction with the accompanying drawings in which:

FIG. 1A is a layout of a semiconductor device according to an example embodiment of the inventive concepts; FIG. 1B is a cross-sectional view of the semiconductor device taken along line I-I′ of FIG. 1A;

FIGS. 2A to 2G are cross-sectional views of semiconductor devices according to some example embodiments of the inventive concepts;

FIG. 3 is a flowchart of a method of fabricating a semiconductor device, according to an example embodiment of the inventive concepts;

FIGS. 4A to 4G are cross-sectional views illustrating a process of fabricating a semiconductor device, according to an example embodiment of the inventive concepts;

FIG. 5 is a cross-sectional view of a high-bandwidth memory package according to an example embodiment of the inventive concepts; and

FIGS. 6A and 6B are enlarged views of regions POR1 to POR5 illustrated in FIG. 5.

### DETAILED DESCRIPTION

Hereinafter, some example embodiments of the inventive concepts will be described in detail with reference to the accompanying drawings. The same reference numerals are used for the same components in the drawings, and repeated descriptions thereof will be omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

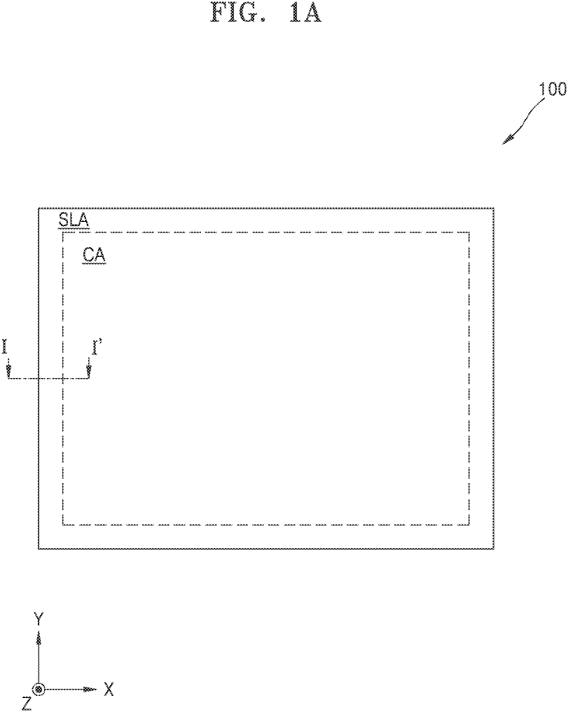

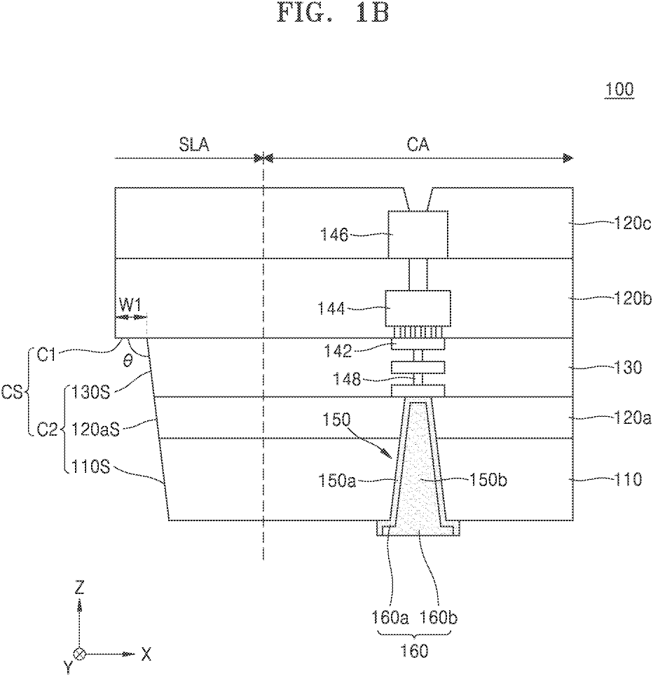

FIG. 1A is a layout of a semiconductor device 100 according to an example embodiment of the inventive concepts. FIG. 1B is a cross-sectional view of the semiconductor device 100 taken along line I-I′ of FIG. 1A.

Referring to FIGS. 1A and 1B, the semiconductor device 100 may have a rectangular shape when viewed in a plan view, but is not limited thereto. The semiconductor device 100 may be a semiconductor chip separated from a wafer through a sawing process.

The semiconductor device 100 may include a semiconductor substrate 110, first to third interlayer insulating layers 120a, 120b, and 120c, a low dielectric layer 130, lower wirings 142, an upper wiring 144, a first pad 146, a vertical contact 148, and a through silicon via 150.

The semiconductor substrate 110 may include a group IV semiconductor (e.g., silicon (Si) or germanium (Ge)), a group IV-IV compound semiconductor (e.g., silicon-germanium (SiGe) or silicon carbide (SiC)), or a group III-V compound semiconductor (e.g., gallium arsenide (GaAs), indium arsenide (InAs), or indium phosphide (InP)). The semiconductor substrate 110 may have a silicon-on-insulator (SOI) structure. For example, the semiconductor substrate 110 may include a buried oxide (BOX) layer. The semiconductor substrate 110 may include a conductive region, for example, a well doped with impurities. The semiconductor substrate 110 may have various device isolation structures such as a shallow trench isolation (STI) structure. The semiconductor substrate 110 may have an active surface and an inactive surface opposite thereto. The semiconductor device including a plurality of individual devices of various types may be formed on the active surface of the semiconductor substrate 110. For example, the plurality of individual devices may include various microelectronic devices, for example, a metal-oxide-semiconductor field-effect transistor (MOSFET) such as a complementary metal-oxide-semiconductor (CMOS) transistor, an image sensor such as a system large-scale integration (LSI) or a CMOS imaging sensor (CIS), a microelectromechanical system (MEMS), an active element, a passive element, and the like. The plurality of individual devices may be electrically connected to the conductive region of the semiconductor substrate 110. The semiconductor device may further include a conductive wiring or a conductive plug that electrically connects at least two of the plurality of individual devices to each other or electrically connects the plurality of individual devices to the conductive region of the semiconductor substrate 110. In addition, each of the plurality of individual devices may be electrically isolated from other adjacent individual devices by an insulating film.

The semiconductor substrate 110 may include a chip area CA in which a plurality of memory cells are arranged, and a scribe lane area SLA horizontally surrounding the chip area CA. Referring to FIGS. 1A and 1B, a plurality of integrated circuits, the lower wirings 142, and the upper wiring 144 may be arranged in the chip area CA.

Two directions that are parallel to the top surface of the semiconductor substrate 110 and are perpendicular to each other are defined as X and Y directions, and a direction perpendicular to the top surface of the semiconductor substrate 110 is defined as a Z direction. The X direction, the Y direction, and the Z direction may be perpendicular to each other. Unless otherwise defined in the following drawings, the definitions of the directions are the same as described above.

The first to third interlayer insulating layers 120a, 120b, and 120c, the low dielectric layer 130, the lower wirings 142, and the upper wiring 144 may be arranged on the semiconductor substrate 110.

The first to third interlayer insulating layers 120a, 120b, and 120c may be arranged on the semiconductor substrate 110. For example, the first interlayer insulating layer 120a may be arranged on the semiconductor substrate 110, the second interlayer insulating layer 120b may be arranged on the first interlayer insulating layer 120a, and the third interlayer insulating layer 120c may be arranged on the second interlayer insulating layer 120b. One of skill in the art may easily realize a semiconductor device including four or more interlayer insulating layers, based on the description herein.

In an example embodiment, the first to third interlayer insulating layers 120a, 120b and 120c may include tetraethyl orthosilicate (TEOS). However, the inventive concepts are not limited thereto, and, for example, the first to third interlayer insulating layers 120a, 120b and 120c may include silicon oxide such as phosphosilicate glass (PSG), boro-phosphosilicate glass (BPSG), undoped silicate glass (USG), plasma-enhanced TEOS (PE-TEOS), high-density plasma chemical vapor deposition (HDP-CVD) oxide, or the like.

As a non-limiting example, the first to third interlayer insulating layers 120a, 120b, and 120c may include the same material. For example, each of the first to third interlayer insulating layers 120a, 120b, and 120c may include TEOS.

As a non-limiting example, the first to third interlayer insulating layers 120a, 120b, and 120c may include different materials. For example, the first interlayer insulating layer 120a may include TEOS, and the second interlayer insulating layer 120b and the third interlayer insulating layer 120c may include PSG.

The first to third interlayer insulating layers 120a, 120b, and 120c may extend in a direction parallel to the top surface of the semiconductor substrate 110 (e.g., the X-direction and the Y-direction).

The low dielectric layer 130 may be arranged between the first interlayer insulating layer 120a and the second interlayer insulating layer 120b. The low dielectric layer 130 may reduce parasitic capacitance between the lower wirings 142, and thus reduce an RC delay of the semiconductor device 100. The dielectric constant of the low dielectric layer 130 may be less than that of silicon oxide (e.g., SiO₂). For example, the low dielectric layer 130 may include a material having a dielectric constant of about 2.2 to about 2.4. The low dielectric layer 130 may be a silicon oxide layer including hydrocarbon (CₓH_{y}). For example, the low dielectric layer 130 may include a SiOC layer or a SiCOH layer. The low dielectric layer 130 may extend in a direction parallel to the top surface of the semiconductor substrate 110.

The lower wirings 142 may be arranged in the low dielectric layer 130, and the upper wiring 144 may be arranged in the second interlayer insulating layer 120b. The lower wirings 142 and the upper wiring 144 may be connected to each other through the vertical contact 148. In addition, the lower wirings 142 and the upper wiring 144 may provide a path for transmitting external operating power and signals to the integrated circuits on the semiconductor substrate 110.

The lower wirings 142, the upper wiring 144, and the vertical contact 148 may include a metal such as aluminum (Al), copper (Cu), or tungsten (W). In an example embodiment, the lower wirings 142, the upper wiring 144, and the vertical contact 148 may include a barrier layer and a wiring metal layer. The barrier layer may include, for example, a metal such as Ti, Ta, Al, Ru, Mn, Co, or W, a nitride of the metal, an oxide of the metal, or an alloy such as cobalt tungsten phosphide (CoWP), cobalt tungsten boron (CoWB), or cobalt tungsten boron phosphide (CoWBP). The wiring metal layer may include at least one metal selected from W, Al, Ti, Ta, Ru, Mn, and Cu.

The first pad 146 may be covered by the third interlayer insulating layer 120c. The third interlayer insulating layer 120c may include an opening exposing at least a portion of the top surface of the first pad 146. The first pad 146 may include the same material as those of the lower wirings 142, the upper wiring 144, and the vertical contact 148. The first pad 146 may include a barrier layer and a metal layer, both of which may include the same material as those of the barrier layers and the metal layers of the lower wirings 142, the upper wiring 144, and the vertical contact 148.

The through silicon via 150 may extend from the bottom surface of the semiconductor substrate 110 to the top surface of the first interlayer insulating layer 120a in a first direction (e.g., the Z direction) perpendicular to the bottom surface of the semiconductor substrate 110, to be connected to the lower wirings 142. In this case, the top and bottom surfaces of the through silicon via 150 may be parallel to the bottom surface of the semiconductor substrate 110. In an example embodiment, the length (hereinafter, referred to as a horizontal width) of the through silicon via 150 in a first horizontal direction (e.g., the X direction) may increase in the direction from one surface of the through silicon via 150 to the other surface of the through silicon via 150. For example, the horizontal width of the through silicon via 150 may increase the direction from the top surface of the through silicon via 150 to the bottom surface of the through silicon via 150. In an example embodiment, the through silicon via 150 may include a barrier layer 150a and a metal layer 150b. The barrier layer 150a may surround the top surface and both sidewalls of the metal layer 150b. In an example embodiment, the barrier layer 150a and the metal layer 150b may include the same material as those of the barrier layers and the metal layers of the lower wirings 142, the upper wiring 144, and the vertical contact 148.

The through silicon via 150 may include a second pad 160. The second pad 160 may include a barrier layer 160a and a metal layer 160b. In an example embodiment, the barrier layer 160a and the metal layer 160b may include the same material as those of the barrier layers and the metal layers of the lower wirings 142, the upper wiring 144, and the vertical contact 148.

In an example embodiment, the barrier layer 150a of the through silicon via 150 and the barrier layer 160a of the second pad 160 may include the same material. For example, both the barrier layer 150a of the through silicon via 150 and the barrier layer 160a of the second pad 160 may include Ti. In another example embodiment, the metal layer 150b of the through silicon via 150 and the metal layer 160b of the second pad 160 may include the same material. For example, both the metal layer 150b of the through silicon via 150 and the metal layer 160b of the second pad 160 may include Cu.

The scribe lane area SLA may be a region in which a separation process, a cutting process, or a dicing process is performed to singulate the wafer into the semiconductor chips, and the integrated circuits, the lower wirings 142, and the upper wiring 144 may not be arranged in the scribe lane area SLA. The semiconductor chips before being separated at the wafer level may be spaced apart from each other with the scribe lane area SLA therebetween.

The semiconductor substrate 110, the first interlayer insulating layer 120a, and the low dielectric layer 130 may constitute a chamfered structure CS that includes a first chamfered surface C1 parallel to the top surface of the semiconductor substrate 110, and a second chamfered surface C2, which is inclined with respect to the top surface of the semiconductor substrate 110 and connected to the first chamfered surface C1.

In an example embodiment, the chamfered structure CS may be in the semiconductor substrate 110, the first interlayer insulating layer 120a, and the low dielectric layer 130, in the scribe lane area SLA. In an example embodiment, the chamfered structure CS may horizontally surround the chip area CA.

As a non-limiting example, the first chamfered surface C1 may be at a same or substantially similar level as the top surface of the low dielectric layer 130. The first chamfered surface C1 may be a portion of the bottom surface of the second interlayer insulating layer 120b, which is not covered by the first interlayer insulating layer 120a and is thus exposed.

In an example embodiment, a horizontal width W1 of the first chamfered surface C1 may be about 1 um to about 15 um. For example, the horizontal width W1 of the first chamfered surface C1 may be about 2.5 um.

In an example embodiment, the second chamfered surface C2 may include a first side surface 110S of the semiconductor substrate 110, a second side surface 120aS of the first interlayer insulating layer 120a, and a third side surface 130S of the low dielectric layer 130. In an example embodiment, the first to third side surfaces 110S, 120aS, and 130S may be on the same plane (e.g., on the second chamfered surface C2).

In an example embodiment, the second chamfered surface C2 may be inclined toward the chip area CA. In an example embodiment, an angle θ between the second chamfered surface C2 and the first chamfered surface C1 may be about 94° to about 110°. For example, the angle θ between the second chamfered surface C2 and the first chamfered surface C1 may be about 97°.

In an example embodiment, the length of the second chamfered surface C2 may be in about 30 um to about 60 um.

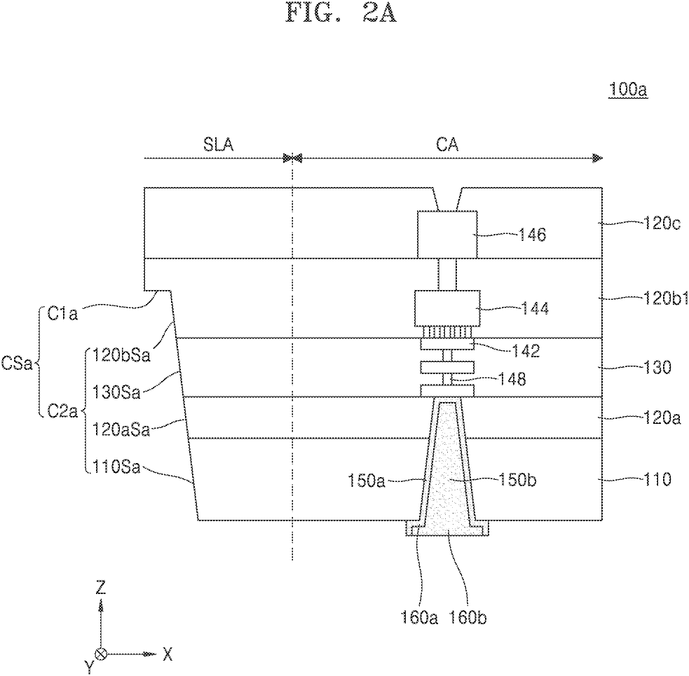

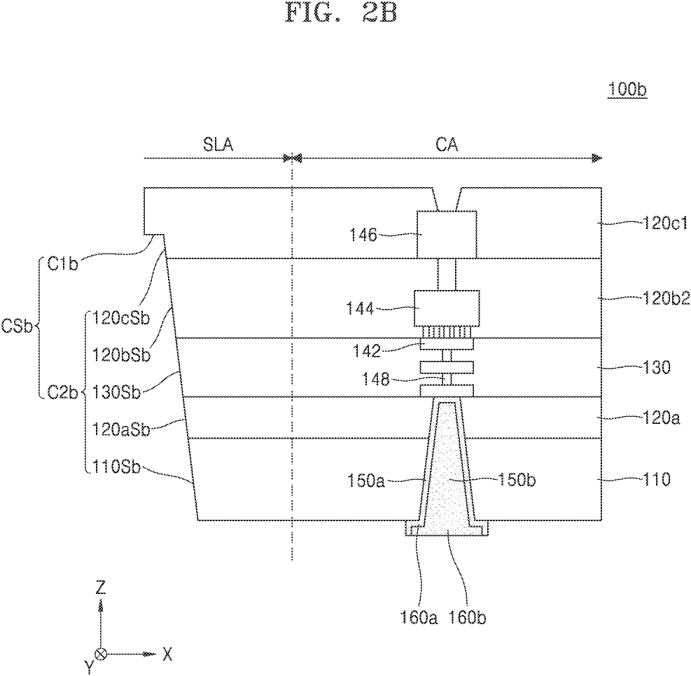

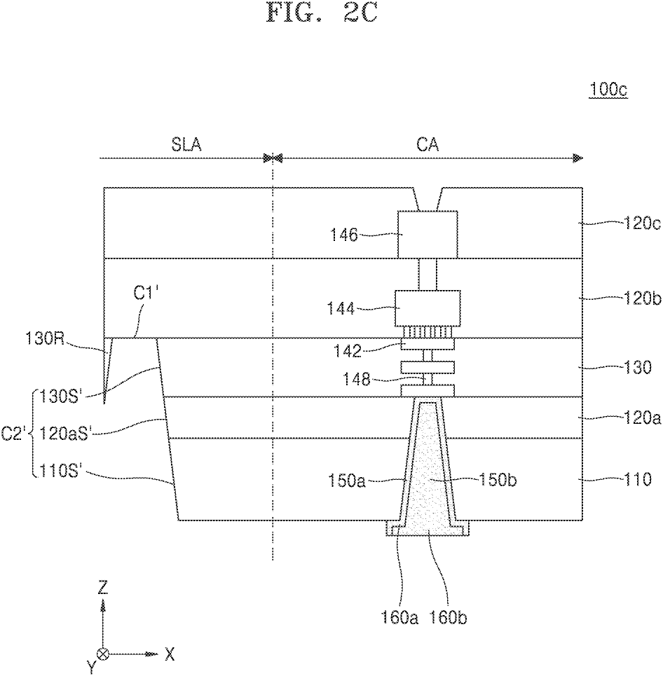

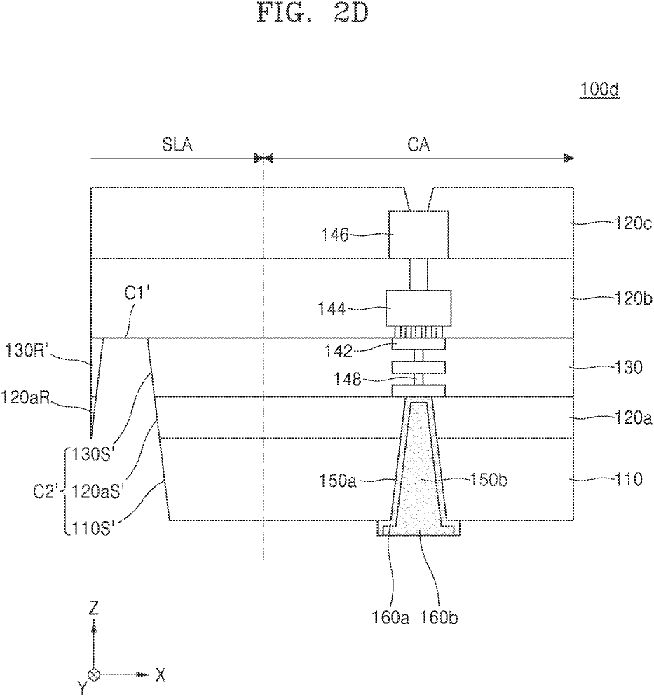

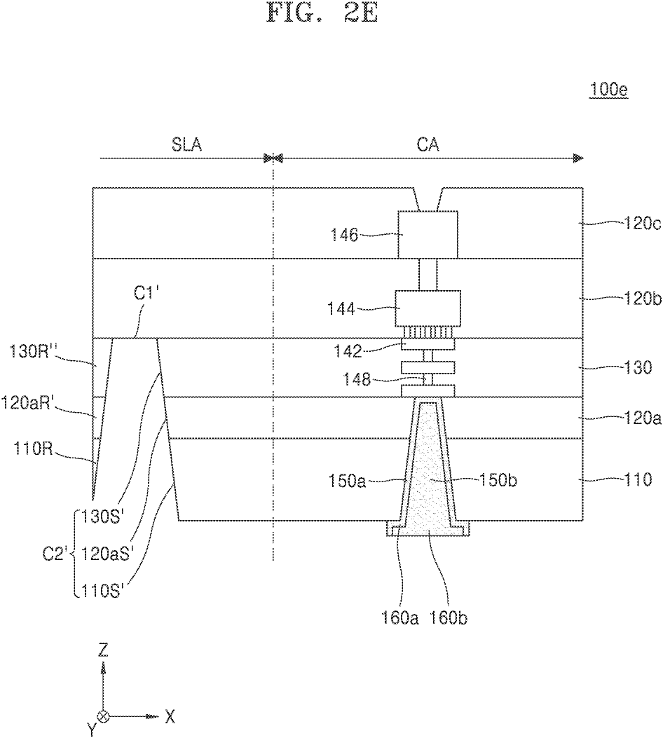

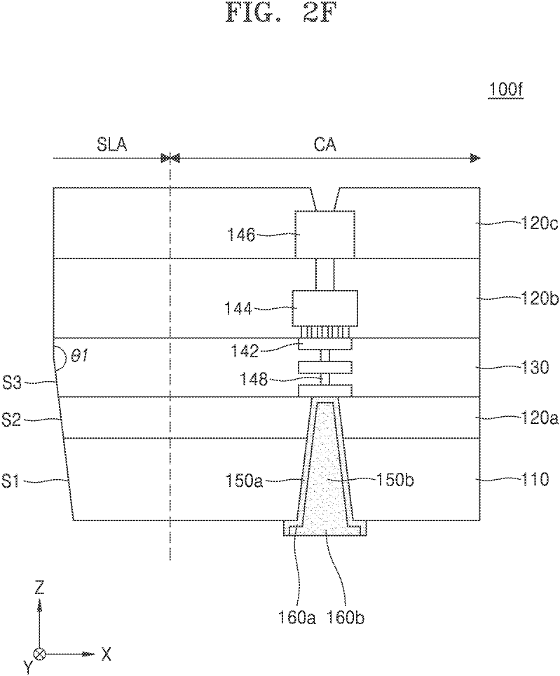

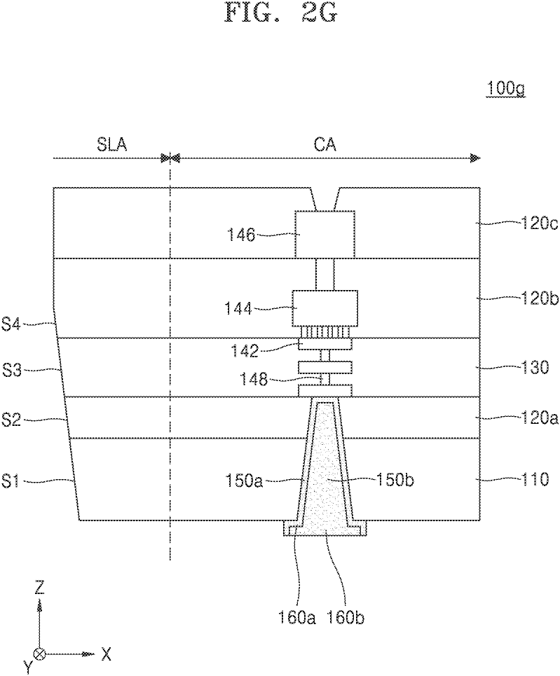

FIGS. 2A and 2B are cross-sectional views of semiconductor devices 100a and 100b according to some example embodiments of the inventive concepts. FIGS. 2A and 2B illustrate portions corresponding to FIG. 1B. The configurations of the semiconductor devices 100a and 100b illustrated in FIGS. 2A and 2B are similar to that of the semiconductor device 100 illustrated in FIG. 1B, and thus the following description will focus on the differences from the semiconductor device 100 illustrated in FIG. 1B.

Referring to FIG. 2A, the semiconductor substrate 110, the first interlayer insulating layer 120a, the low dielectric layer 130, and a second interlayer insulating layer 120b1 may constitute a chamfered structure CSa including a first chamfered surface C1a parallel to the top surface of the semiconductor substrate 110 and a second chamfered surface C2a, which is inclined with respect to the top surface of the semiconductor substrate 110 and connected to the first chamfered surface C1a.

In an example embodiment, the first chamfered surface C1a may be between the top surface of the second interlayer insulating layer 120b1 and the bottom surface of the second interlayer insulating layer 120b1.

In an example embodiment, the second chamfered surface C2a may include a first side surface 110Sa of the semiconductor substrate 110, a second side surface 120aSa of the first interlayer insulating layer 120a, a third side surface 130Sa of the low dielectric layer 130, and a fourth side surface 120bSa of the second interlayer insulating layer 120b1. In an example embodiment, the first to fourth side surfaces 110Sa, 120aSa, 130Sa and 120bSa may be on the same plane (e.g., on the second chamfered surface C2a).

Referring to FIG. 2B, the semiconductor substrate 110, the first interlayer insulating layer 120a, the low dielectric layer 130, a second interlayer insulating layer 120b2, and a third interlayer insulating layer 120c1 may constitute a chamfered structure CSb including a first chamfered surface C1b parallel to the top surface of the semiconductor substrate 110 and a second chamfered surface C2b, which is inclined with respect to the top surface of the semiconductor substrate 110 and connected to the first chamfered surface C1b.

In an example embodiment, the first chamfered surface C1b may be between the top surface of the third interlayer insulating layer 120c1 and the bottom surface of the third interlayer insulating layer 120c1.

In an example embodiment, the second chamfered surface C2b may include a first side surface 110Sb of the semiconductor substrate 110, a second side surface 120aSb of the first interlayer insulating layer 120a, a third side surface 130Sb of the low dielectric layer 130, a fourth side surface 120bSb of the second interlayer insulating layer 120b2, and a fifth side surface 120cSb of the third interlayer insulating layer 120c1. In an example embodiment, the first to fifth side surfaces 110Sb, 120aSb, 130Sb, 120bSb, 120cSb may be on the same plane (e.g., the second chamfered surface C2b).

FIGS. 2C to 2E are cross-sectional views of semiconductor devices 100c, 100d, and 100e according to some example embodiments of the inventive concepts. FIGS. 2C and 2E illustrate portions corresponding to FIG. 1B. The configurations of the semiconductor devices 100c, 100d, and 100e illustrated in FIGS. 2C to 2E are similar to that of the semiconductor device 100 illustrated in FIG. 1B, and thus the following description will focus on the differences from the semiconductor device 100 illustrated in FIG. 1B.

Referring to FIG. 2C, the semiconductor device 100c may further include a residual low dielectric layer 130R arranged on the bottom surface of the second interlayer insulating layer 120b in the scribe lane area SLA and horizontally spaced apart from the low dielectric layer 130. In an example embodiment, the residual low dielectric layer 130R may horizontally surround the low dielectric layer 130. In an example embodiment, the residual low dielectric layer 130R may have a triangular shape.

Referring to FIG. 2D, the semiconductor device 100d may further include a residual low dielectric layer 130R′ arranged on the bottom surface of the second interlayer insulating layer 120b in the scribe lane area SLA and horizontally spaced apart from the low dielectric layer 130, and a first residual interlayer insulating layer 120aR arranged on the bottom surface of the residual low dielectric layer 130R′ and horizontally spaced apart from the first interlayer insulating layer 120a. In an example embodiment, the first residual interlayer insulating layer 120aR may horizontally surround the first interlayer insulating layer 120a. In an example embodiment, the residual low dielectric layer 130R′ may have a trapezoidal shape, and the first residual interlayer insulating layer 120aR may have a triangular shape. In this case, the horizontal width of the top surface of the residual low dielectric layer 130R′ having the trapezoidal shape may be greater than the horizontal width of the bottom surface thereof.

Referring to FIG. 2E, the semiconductor device 100e may further include a residual low dielectric layer 130R″ arranged on the bottom surface of the second interlayer insulating layer 120b in the scribe lane area SLA and horizontally spaced apart from the low dielectric layer 130, a first residual interlayer insulating layer 120aR' arranged on the bottom surface of the residual low dielectric layer 130R″ and horizontally spaced apart from the first interlayer insulating layer 120a, and a residual semiconductor substrate 110R arranged on the bottom surface of the first residual interlayer insulating layer 120aR' and horizontally spaced apart from the semiconductor substrate 110. In an example embodiment, the residual semiconductor substrate 110R may horizontally surround the semiconductor substrate 110. In an example embodiment, the residual low dielectric layer 130R″ and the first residual interlayer insulating layer 120aR' may have a trapezoidal shape, and the residual semiconductor substrate 110R may have a triangular shape.

FIGS. 2F and 2G are cross-sectional views of semiconductor devices 100f and 100g according to some example embodiments of the inventive concepts. FIGS. 2F and 2G illustrate portions corresponding to FIG. 1B. The configurations of the semiconductor devices 100f and 100g illustrated in FIGS. 2F and 2G are similar to that of the semiconductor device 100 illustrated in FIG. 1B, and thus the following description will focus on the differences from the semiconductor device 100 illustrated in FIG. 1B.

Referring to FIG. 2F, a first side surface S1 of the semiconductor substrate 110, a second side surface S2 of the first interlayer insulating layer 120a, and a third side surface S3 of the low dielectric layer 130 of the semiconductor device 100f may be inclined with respect to the top surface of the semiconductor substrate 110. In an example embodiment, the first to third side surfaces S1, S2, and S3 may be on the same plane. In an example embodiment, the first to third side surfaces S1, S2 and S3 may be inclined toward the chip area CA. In an example embodiment, an angle θ1 between the first to third side surfaces S1, S2, and S3 and the side surface of the second interlayer insulating layer 120b may be about 160° to about 176°.

Referring to FIG. 2G, a fourth side surface S4 of the second interlayer insulating layer 120b of the semiconductor device 100g may be inclined with respect to the top surface of the semiconductor substrate 110. In an example embodiment, the first to fourth side surfaces S1, S2, S3, and S4 may be on the same plane. In an example embodiment, the first to fourth side surfaces S1, S2, S3, and S4 may be inclined toward the chip area CA.

Although not illustrated in FIGS. 2A to 2E, a guard ring may be arranged in the scribe lane area SLA of the semiconductor device 100a, 100b, 100c, 100d, or 100e. The guard ring may prevent or mitigate cracks generated in the scribe lane area SLA from penetrating into the chip area CA. The guard ring may have a structure same as or substantially similar to those of some of the lower wirings 142 and the upper wiring 144, and may be formed together when the corresponding lower wiring 142s and upper wiring 144 are formed.

Although not illustrated in FIGS. 2A to 2E, a chipping dam may be arranged in the scribe lane area SLA to be adjacent to the guard ring. The chipping dam may have a structure same as or substantially similar to that of the guard ring and mitigate or prevent cracks from penetrating into the chip area CA.

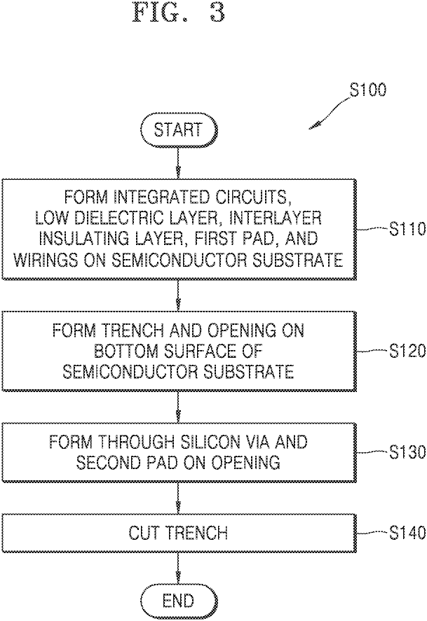

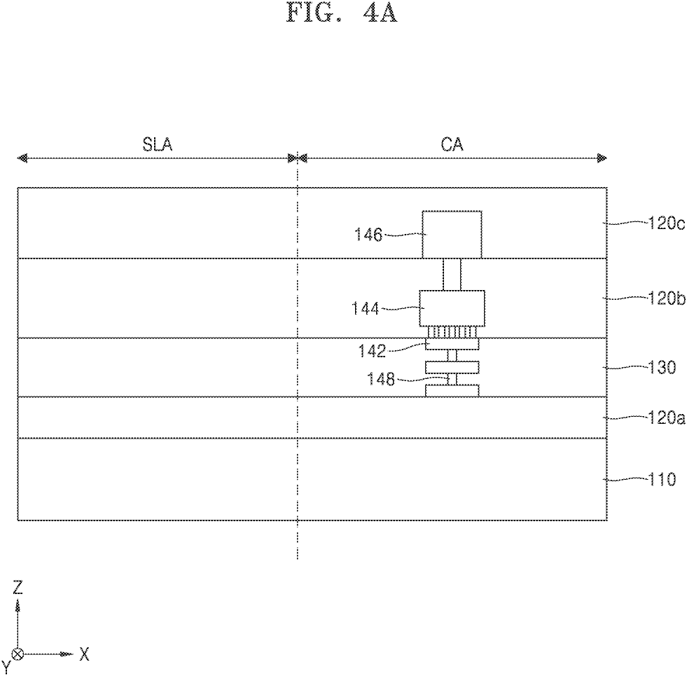

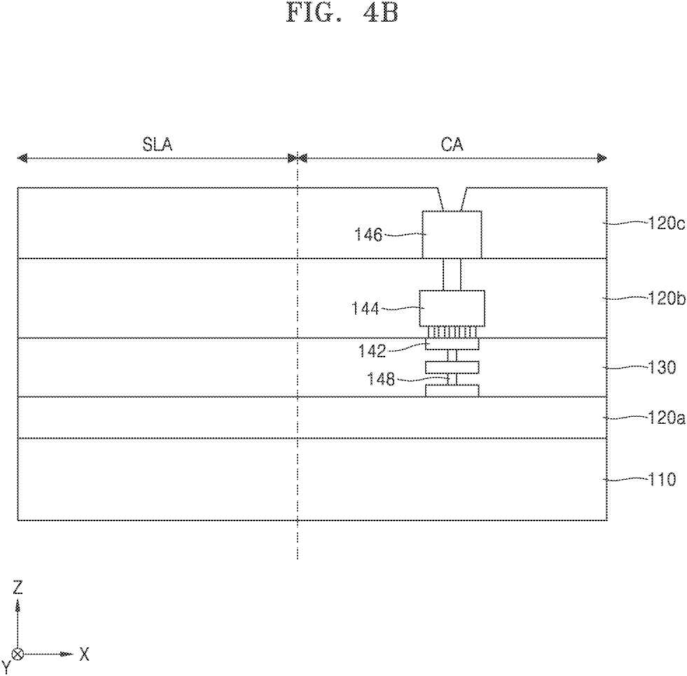

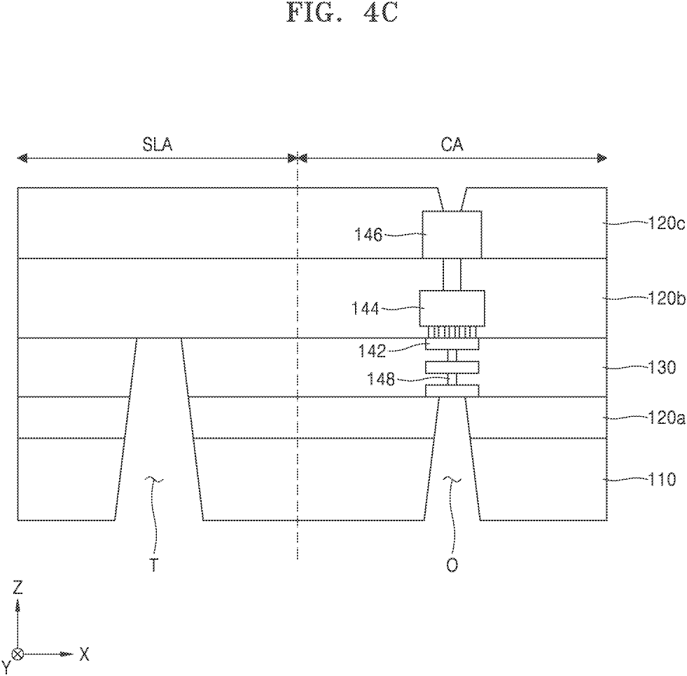

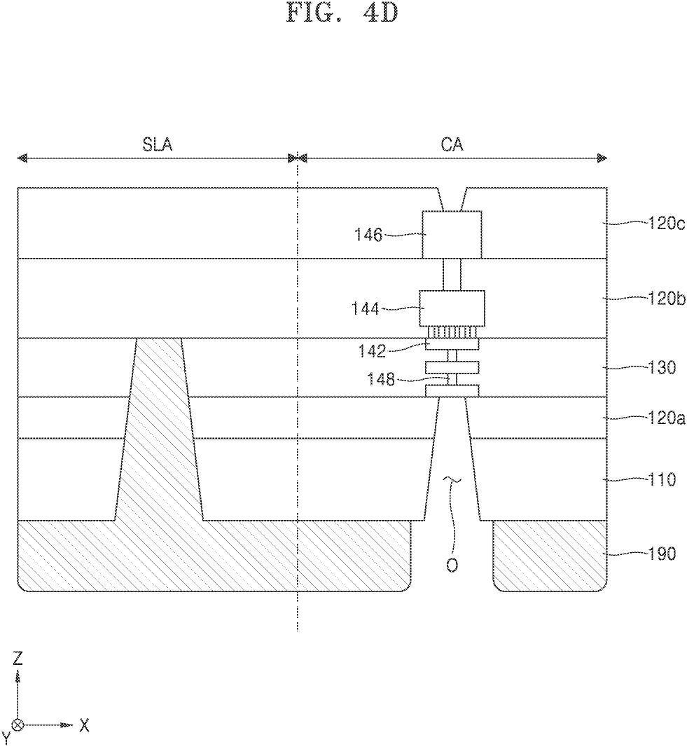

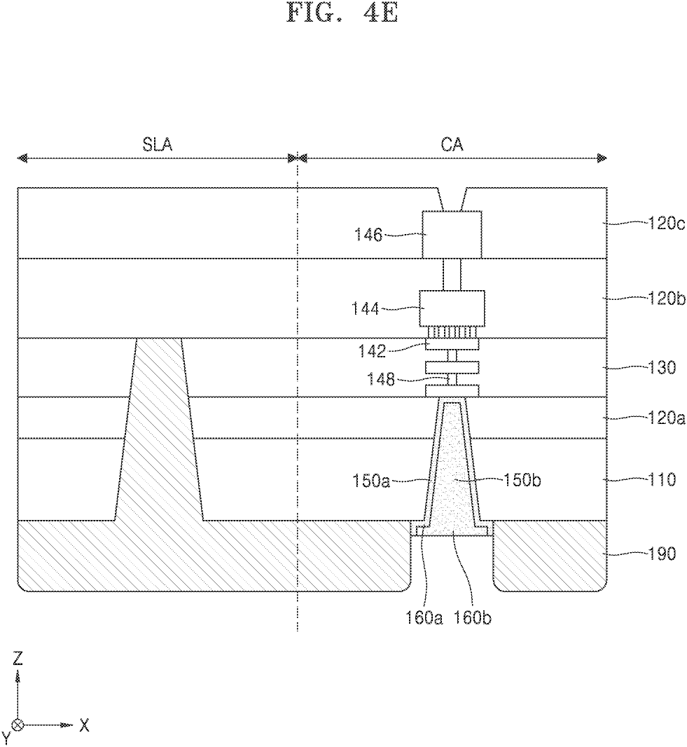

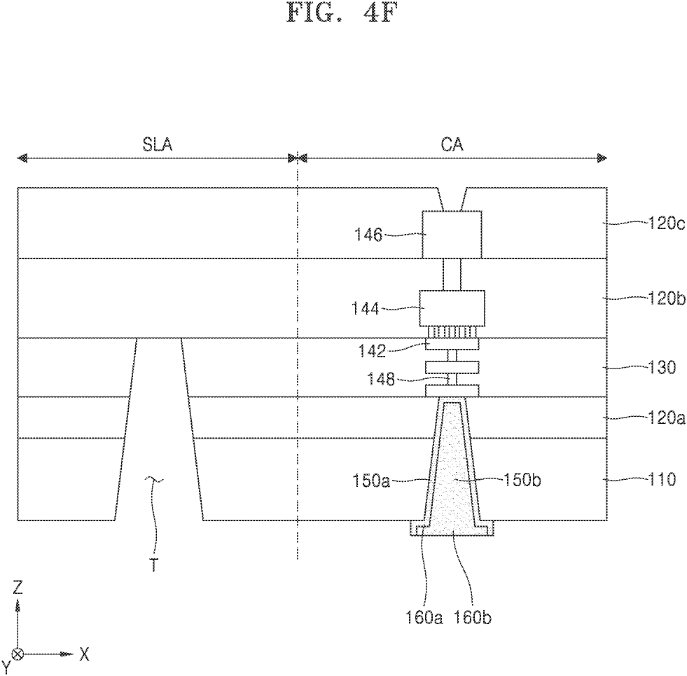

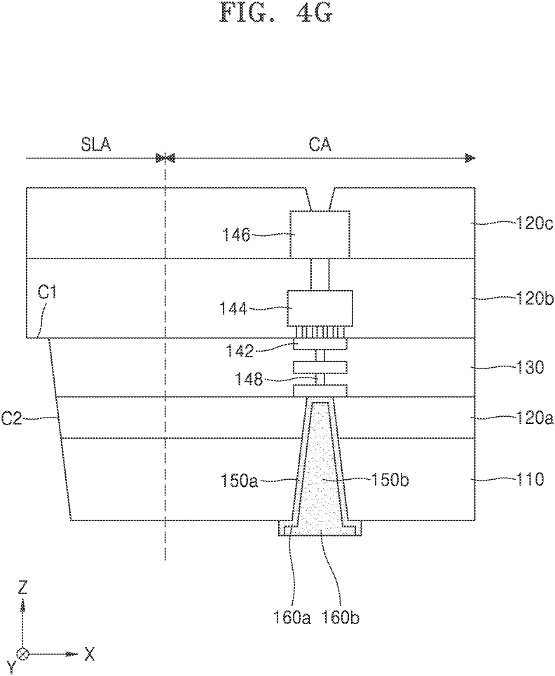

FIG. 3 is a flowchart of a method of fabricating the semiconductor device 100, according to an example embodiment of the inventive concepts. FIGS. 4A to 4G are cross-sectional views illustrating respective operations of a process of fabricating the semiconductor device 100, according to an example embodiment of the inventive concepts.

Referring to FIGS. 3 and 4A, integrated circuits, first to third interlayer insulating layers 120a, 120b, 120c, the low dielectric layer 130, the lower wirings 142, the upper wiring 144, and the first pad 146 may be formed on the semiconductor substrate 110 (S110). The first to third interlayer insulating layers 120a, 120b, 120c and the low dielectric layer 130 may be formed by performing a method such as chemical vapor deposition (CVD), physical vapor deposition (PVD), or atomic layer deposition (ALD).

Although the first to third interlayer insulating layers 120a, 120b, and 120c are illustrated in FIG. 4A, the inventive concepts are not limited thereto. The lower wirings 142 and the upper wiring 144 may be formed in the low dielectric layer 130 and the second interlayer insulating layer 120b, respectively. The first pad 146 may be formed in the third interlayer insulating layer 120c. The first pad 146 may be formed by forming a groove in the second interlayer insulating layer 120b to expose the top surface of the upper wiring 144 and forming a barrier layer and a metal layer in the groove.

Referring to FIGS. 3 and 4B, an opening through which at least a portion of the top surface of the first pad 146 is exposed may be formed in the third interlayer insulating layer 120c by performing a photolithography process and an etching process. In this case, the top surface of the first pad 146 may be located between the top surface and the bottom surface of the third interlayer insulating layer 120c. However, the inventive concepts are not limited thereto. In some example embodiments, unlike in FIG. 4B, the entire top surface of the first pad 146 may be exposed from the third interlayer insulating layer 120c, and the top surface of the first pad 146 may be coplanar with the top surface of the third interlayer insulating layer 120c.

Referring to FIGS. 3 and 4C, a trench T and an opening O may be formed on the bottom surface of the semiconductor substrate 110 (S120). The trench T may be formed in the scribe lane area SLA, and the opening O may be formed in the chip area CA.

The trench T may penetrate the semiconductor substrate 110, the first interlayer insulating layer 120a, and the low dielectric layer 130, but the inventive concepts are not limited thereto. For example, the trench T may partially penetrate the second interlayer insulating layer 120b or the third interlayer insulating layer 120c. The opening O may extend from the bottom surface of the semiconductor substrate 110 to the top surface of the first interlayer insulating layer 120a to expose the bottom surface of the lower wirings 142.

In example embodiments, the trench T for singulation into the semiconductor chips and the opening O for forming the through silicon via 150 (see FIG. 1B) may be simultaneously formed to improve the productivity of the semiconductor device.

In addition, unlike a process in the related art, the semiconductor device 100 according to an example embodiments of the inventive concepts does not need to be subjected to a planarization process because no additional insulating layer is formed on the trench T. Accordingly, the amount of a material to be removed for cutting in a sawing process, which will be described below, is reduced. Therefore, cracks that may occur in the sawing process may be reduced.

Referring to FIGS. 3 and 4D, a photoresist 190 may be coated on the bottom surface of the semiconductor substrate 110. The photoresist 190 may be coated by performing, for example, spin coating. Because the through silicon via 150 needs to be formed in the opening O, the photoresist 190 coated on the opening O may be removed.

Referring to FIGS. 3 and 4E, the through silicon via 150 and the second pad 160 may be formed in the opening O (S130). First, the barrier layers 150a and 160a are deposited on the opening O from which the photoresist 190 is removed. The barrier layers 150a and 160a may be formed by performing, for example, CVD, PVD, ALD, etc. Thereafter, the metal layers 150b and 160b may be formed on the barrier layers 150a and 160a, respectively. In an example embodiment, the barrier layers 150a and 160a may be formed of the same material, and the metal layers 150b and 160b may be formed of the same material. In this case, the barrier layers 150a and 160a may be simultaneously formed by performing a deposition process or the like, and the metal layers 150b and 160b may also be simultaneously formed.

Referring to FIGS. 3 and 4F, after the through silicon via 150 and the second pad 160 are formed, the remaining photoresist 190 may be removed. The photoresist 190 may be removed by performing, for example, a strip process.

Referring to FIG. 4G, the trench T in the scribe lane area SLA may be cut (S140). The cutting process may be, for example, a sawing process using a blade. Because the trench T penetrates the low dielectric layer 130, the cutting process is performed in the second interlayer insulating layer 120b or the third interlayer insulating layer 120c. Accordingly, cracks of the low dielectric layer 130 generated by the cutting by the blade may be reduced. In this case, a portion of the scribe lane area SLA may not be cut and remain while forming the chamfered structure CS. Thereafter, in a process of forming a molding layer, the molding layer may fill the chamfered structure CS.

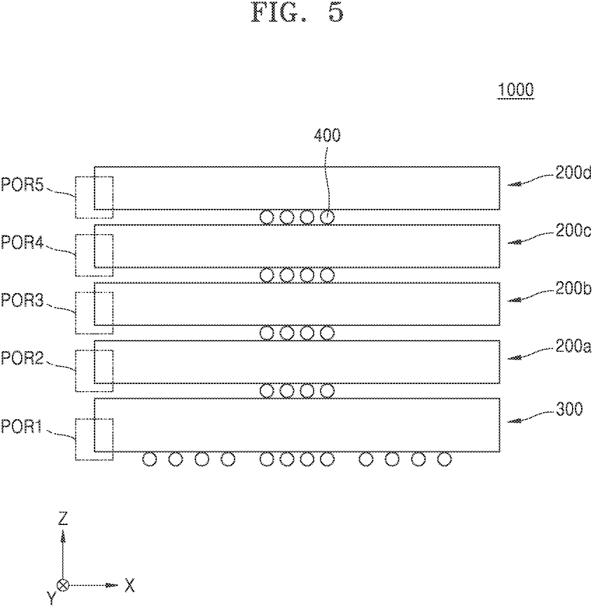

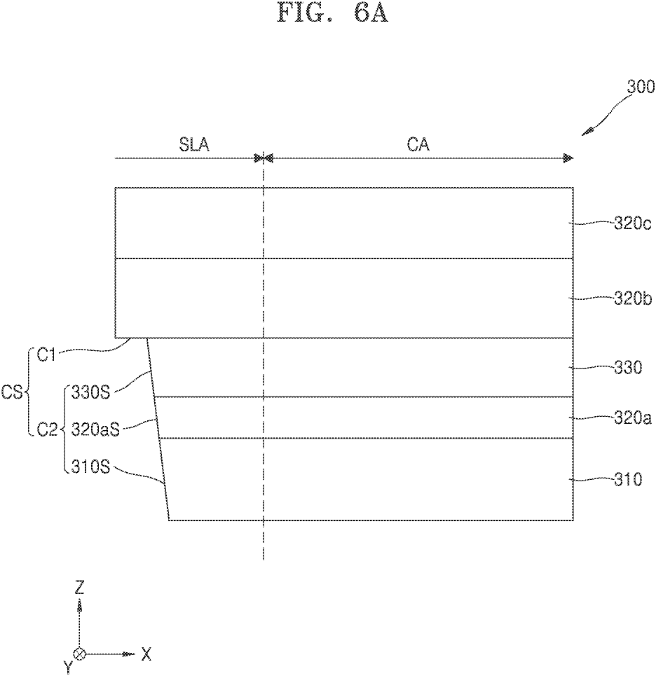

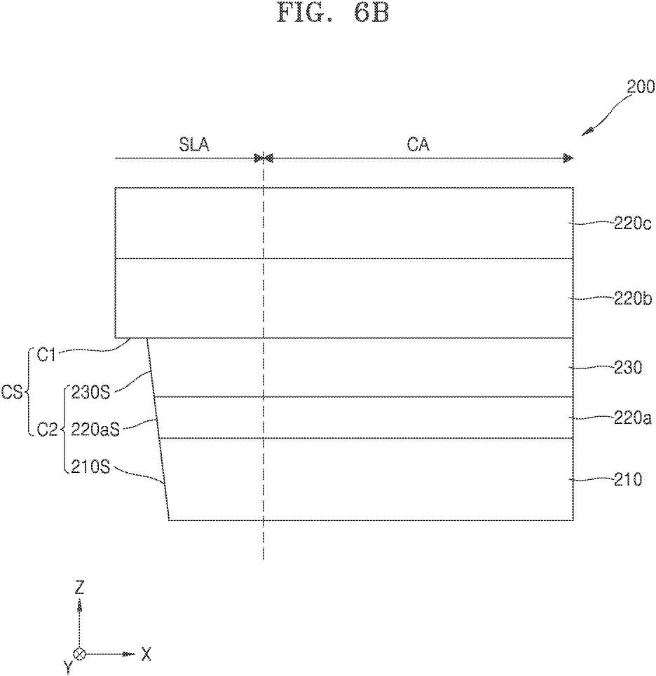

FIG. 5 is a cross-sectional view of a high-bandwidth memory (HBM) package 1000 according to an example embodiment of the inventive concepts. FIGS. 6A and 6B are enlarged views of regions POR1 to POR5 illustrated in FIG. 5, respectively. FIG. 6A is an enlarged view of the region POR1, and FIG. 6B is an enlarged view of the regions POR2 to POR5.

Referring to FIG. 5, the HBM package 1000 may include memory chips 200a, 200b, 200c and 200d, a base chip 300, and micro-bumps 400. The memory chips 200a, 200b, 200c and 200d may be sequentially stacked on the base chip 300, and the micro bumps 400 may be arranged between the base chip 300 and the memory chip 200a, and between the memory chips 200b, 200c and 200d.

Referring to FIGS. 5 and 6A, the base chip 300 may include a first semiconductor substrate 310, a first lower interlayer insulating layer 320a, a first upper interlayer insulating layer 320b, a first uppermost interlayer insulating layer 320c, and a first low dielectric layer 330. The first semiconductor substrate 310, the first lower interlayer insulating layer 320a, the first upper interlayer insulating layer 320b, the first uppermost interlayer insulating layer 320c, and the first low dielectric layer 330 may be the same as or substantially similar to the semiconductor substrate 110, the first to third interlayer insulating layers 120a, 120b, and 120c, and the low dielectric layer 130, which are described with reference to FIG. 1B, respectively. In a non-limiting example embodiment, the base chip 300 may be the semiconductor device 100 described with reference to FIG. 1B. That is, the base chip 300 may include the chamfered structure CS including the first chamfered surface C1 parallel to the top surface of the first semiconductor substrate 310, and the second chamfered surface C2, which is inclined with respect to the top surface of the first semiconductor substrate 310 and connected to the first chamfered surface C1. In a non-limiting example embodiment, the first chamfered surface C1 may be at the same level as the top surface of the first low dielectric layer 330. In an example embodiment, the second chamfered surface C2 may include a first side surface 310S of the first semiconductor substrate 310, a second side surface 320aS of the first lower interlayer insulating layer 320a, and a third side surface 330S of the first low dielectric layer 330. The first to third side surfaces 310S, 320aS, and 330S may be on the same plane. Unlike in FIG. 6A, in a non-limiting example embodiment, the base chip 300 may be any one of the semiconductor devices 100a, 100b, 100c, 100d, 100e, 100f, and 100g described with reference to FIGS. 2A to 2G. In an example embodiment, both side surfaces of the base chip 300 may include the chamfered structure CS. That is, the chamfered structure CS may be formed on both the region POR1 of the base chip 300 illustrated in FIG. 5 and a region of the side surface opposite to the region POR1.

In an example embodiment, the base chip 300 may be, for example, a logic chip. The logic chip may be, for example, a microprocessor, an analog device, or a digital signal processor. The base chip 300 may integrate signals of the memory chips 200a, 200b, 200c, and 200d and transmit the integrated signals to the outside, and may transmit signals and power from the outside to the memory chips 200a, 200b, 200c, and 200d. The base chip 300 may include a through silicon via (not shown). The through silicon via may include a conductive layer and a via insulating layer. The conductive layer may include, for example, a metal such as W, Al, Ti, Ta, Co, and Cu. The via insulating layer may include, for example, an insulating material such as silicon oxide (SiO₂) or silicon nitride (SiN).

Referring to FIGS. 5 and 6B, each of the memory chips 200a, 200b, 200c, and 200d may include a second semiconductor substrate 210, a second lower interlayer insulating layer 220a, a second upper interlayer insulating layer 220b, a second uppermost interlayer insulating layer 220c, and a second low dielectric layer 230. The second semiconductor substrate 210, the second lower interlayer insulating layer 220a, the second upper interlayer insulating layer 220b, the second uppermost interlayer insulating layer 220c, and the second low dielectric layer 230 may be the same as or substantially similar to the semiconductor substrate 110, the first to third interlayer insulating layers 120a, 120b, and 120c, and the low dielectric layer 130, which are described with reference to FIG. 1B, respectively. In a non-limiting example embodiment, at least one of the memory chips 200a, 200b, 200c, and 200d may be the semiconductor device 100 described with reference to FIG. 1B. For example, each of the memory chips 200a and 200b may be the semiconductor device 100 described with reference to FIG. 1B. Unlike in FIG. 6B, in a non-limiting example embodiment, at least one of the memory chips 200a, 200b, 200c, and 200d may be any one of the semiconductor devices 100a, 100b, 100c, 100d, 100e, 100f, and 100g described with reference to FIGS. 2A to 2G. For example, each of the memory chips 200a and 200b may be the semiconductor device 100 described with reference to FIG. 1B, the memory chip 200c may be the semiconductor device 100a described with reference to FIG. 2A, and the memory chip 200d may be the semiconductor device 100d described with reference to FIG. 2D. In an example embodiment, both side surfaces of each of the memory chips 200a, 200b, 200c and 200d may include the chamfered structure CS. That is, the chamfered structure CS may be formed on each of the regions POR2 to POR5 of the memory chips 200a, 200b, 200c, and 200d illustrated in FIG. 5 and regions of the side surfaces of the memory chips 200a, 200b, 200c, and 200d opposite thereto (e.g., opposite to the regions POR2 to POR5).

In an example embodiment, memory chips 200 may be, for example, volatile memory chips such as dynamic random-access memory (DRAM) or static random-access memory (SRAM), or nonvolatile memory chips such as phase-change random-access memory (PRAM), magnetoresistive random-access memory (MRAM), ferroelectric random-access memory (FeRAM), or resistive random-access memory (RRAM). The memory chips 200 may include a through silicon via (not shown). The through silicon via may include a conductive layer and a via insulating layer. The conductive layer and the via insulating layer may include the same material as those of the conductive layer and the via insulating layer of the base chip 300, respectively.

The micro-bumps 400 may be arranged between the base chip 300 and the memory chips 200 to electrically connect the base chip 300 and the memory chips 200 to each other. The micro-bumps 400 may be in contact with the through silicon vias included in the base chip 300 and the memory chips 200. The micro-bumps 400 may include, for example, Cu, but are not limited thereto.

The HBM package 1000 may be fabricated by stacking the memory chips 200 on the base chip 300 in a wafer state, molding the memory chips 200 and the base chip 300 with a molding layer, and performing singulation through a sawing process.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a semiconductor substrate comprising a chip area and a scribe lane area, the chip area including a plurality of memory cells, the scribe lane area horizontally surrounding the chip area;
a first interlayer insulating layer on the semiconductor substrate in the chip area and the scribe lane area;
a low dielectric layer on the first interlayer insulating layer in the chip area and the scribe lane area;
a second interlayer insulating layer on the low dielectric layer in the chip area and the scribe lane area;
a third interlayer insulating layer on the second interlayer insulating layer in the chip area and the scribe lane area; and
a through silicon via penetrating the semiconductor substrate and the first interlayer insulating layer in a direction perpendicular to a top surface of the semiconductor substrate in the chip area,
wherein each of the semiconductor substrate, the first interlayer insulating layer, and the low dielectric layer comprises a chamfered structure that includes a first chamfered surface and a second chamfered surface, the first chamfered surface being parallel to the top surface of the semiconductor substrate, the second chamfered surface being inclined with respect to the top surface of the semiconductor substrate and connected to the first chamfered surface.

2. The semiconductor device of claim 1, wherein the chamfered structure is in the scribe lane area.

3. The semiconductor device of claim 1, wherein the second chamfered surface is inclined toward the chip area.

4. The semiconductor device of claim 1, wherein an angle between the first chamfered surface and the second chamfered surface is 94° to 110°.

5. The semiconductor device of claim 1, wherein a length of the second chamfered surface is 30 um to 60 um.

6. The semiconductor device of claim 1, wherein the first chamfered surface is at a same level as a top surface of the low dielectric layer.

7. The semiconductor device of claim 1, wherein the first chamfered surface is between a top surface and a bottom surface of the second interlayer insulating layer.

8. The semiconductor device of claim 1, wherein the first chamfered surface is between a top surface and a bottom surface of the third interlayer insulating layer.

9. The semiconductor device of claim 1, wherein a horizontal width of the first chamfered surface is 1 um to 15 um.

10. The semiconductor device of claim 1, wherein the chamfered structure horizontally surrounds the chip area.

11. The semiconductor device of claim 1, further comprising:
a residual low dielectric layer on a bottom surface of the second interlayer insulating layer in the scribe lane area and horizontally spaced apart from the low dielectric layer,
wherein the residual low dielectric layer horizontally surrounds the low dielectric layer.

12. The semiconductor device of claim 11, further comprising:
a first residual interlayer insulating layer on a bottom surface of the residual low dielectric layer and horizontally spaced apart from the first interlayer insulating layer,
wherein the first residual interlayer insulating layer horizontally surrounds the first interlayer insulating layer.

13. The semiconductor device of claim 12, further comprising:
a residual semiconductor substrate on a bottom surface of the first residual interlayer insulating layer and horizontally spaced apart from the semiconductor substrate,
wherein the residual semiconductor substrate horizontally surrounds the semiconductor substrate.

14. A semiconductor device comprising:
a semiconductor substrate comprising a chip area and a scribe lane area, the chip area including a plurality of memory cells, the scribe lane area horizontally surrounding the chip area;
a first interlayer insulating layer on the semiconductor substrate in the chip area and the scribe lane area;
a low dielectric layer on the first interlayer insulating layer in the chip area and the scribe lane area;
a lower wiring layer in the low dielectric layer in the chip area;
a second interlayer insulating layer on the low dielectric layer in the chip area and the scribe lane area;
an upper wiring layer in the second interlayer insulating layer in the chip area;
a third interlayer insulating layer on the second interlayer insulating layer in the chip area and the scribe lane area; and
a through silicon via penetrating the semiconductor substrate and the first interlayer insulating layer in a direction perpendicular to a top surface of the semiconductor substrate in the chip area,
wherein a first side surface of the semiconductor substrate, a second side surface of the first interlayer insulating layer, and a third side surface of the low dielectric layer are inclined with respect to the top surface of the semiconductor substrate.

15. The semiconductor device of claim 14, wherein the first to third side surfaces are inclined toward the chip area.

16. The semiconductor device of claim 14, wherein the first to third side surfaces are on a same plane.

17. The semiconductor device of claim 14, wherein a fourth side surface of the second interlayer insulating layer is inclined with respect to the top surface of the semiconductor substrate and toward the chip area.

18. The semiconductor device of claim 14, wherein an angle between the first to third side surfaces and a side surface of the second interlayer insulating layer is 170° to 176°.

19. A semiconductor package comprising:
a base chip comprising a first semiconductor substrate, the first semiconductor substrate including a first chip area and a first scribe lane area, the first chip area including a plurality of memory cells, the first scribe lane area horizontally surrounding the first chip area, the base chip comprising,
a first lower interlayer insulating layer on the first semiconductor substrate in the first chip area and the first scribe lane area,
a first low dielectric layer on the first lower interlayer insulating layer in the first chip area and the first scribe lane area,
a first upper interlayer insulating layer on the first low dielectric layer in the first chip area and the first scribe lane area, and
a first uppermost interlayer insulating layer on the first upper interlayer insulating layer in the first chip area and the first scribe lane area; a memory chip arranged on the base chip; and
micro-bumps between the base chip and the memory chip and connecting the base chip and the memory chip to each other,
wherein the base chip has a chamfered structure that includes a first chamfered surface and a second chamfered surface, the first chamfered surface being parallel to a top surface of the first semiconductor substrate, the second chamfered surface being inclined with respect to the top surface of the first semiconductor substrate and connected to the first chamfered surface.

20. The semiconductor package of claim 19, wherein the memory chip comprises:
a second semiconductor substrate comprising a second semiconductor substrate, the second semiconductor substrate comprising a second chip area and a second scribe lane area, the second chip area including a plurality of memory cells, the second scribe lane area horizontally surrounding the second chip area;
a second lower interlayer insulating layer on the second semiconductor substrate in the second chip area and the second scribe lane area;
a second low dielectric layer on the second lower interlayer insulating layer in the second chip area and the second scribe lane area;
a second upper interlayer insulating layer on the second low dielectric layer in the second chip area and the second scribe lane area; and
a second uppermost interlayer insulating layer on the second upper interlayer insulating layer in the second chip area and the second scribe lane area,
wherein the memory chip has a chamfered structure that includes a third chamfered surface and a fourth chamfered surface, the third chamfered surface being parallel to a top surface of the second semiconductor substrate, the fourth chamfered surface being inclined with respect to the top surface of the second semiconductor substrate and connected to the third chamfered surface.
